(19) United States
(12) Patent Application Publication
(10) Pub. No.: US 2007/0256734 A1
(43) Pub. Date: Nov. 8, 2007

(54) STABILIZED PHOTOVOLTAIC DEVICE AND METHODS FOR ITS MANUFACTURE

(75) Inventors: Subhendu Guha, Bloomfield Hills, MI (US); Chi Yang, Troy, MI (US); Baojie Yan, Rochester Hills, MI (US); Guozhen Yue, Troy, MI (US)

Correspondence Address: GIFFORD, KRASS, SPRINKLE,ANDERSON & CITKOWSKI, P.C, PO BOX 7021, TROY, MI, 48007-7021, US

(73) Assignee: United Solar Ovonic LLC

(21) Appl. No.: 11/744,918

(22) Filed: May 7, 2007

Related U.S. Application Data
(60) Provisional application No. 60/798,547, filed on May 8, 2006.

(51) Int. Cl. H01L 31/00

(52) U.S. Cl. 136/258

(57) ABSTRACT

A semiconductor device of p-i-n type configuration includes a p layer which is comprised of a p-doped semiconductor material, an n layer comprised of an n-doped semiconductor material and an i layer comprised of a substantially intrinsic, nanocrystalline semiconductor material interposed therebetween. The crystalline volume in the i layer decreases as the thickness of said layer increases from its interface with the n layer to its interface with the p layer. The grain size of the substantially intrinsic nanocrystalline semiconductor material may also decrease as the thickness of the i layer increases from its interface with the n layer to its interface with the p layer. The volume of regions of intermediate range order in a portion of the i layer commencing at the interface of the i layer and the p layer, and comprising no more than 50% of the thickness thereof, is greater than is the volume of regions of intermediate range order in the remainder of the i layer. Devices of this type may be used as photovoltaic devices, and may be fabricated by a plasma deposition process.

### CROSS-REFERENCE TO RELATED APPLICATIONS

This application claims priority of U.S. Provisional Patent Application Ser. No. 60/798,547 filed May 8, 2006, entitled “Stabilized Photovoltaic Device and Methods for Its Manufacture”.

### FIELD OF THE INVENTION

This invention generally relates to semiconductor devices. More specifically, the invention relates to photovoltaic devices. Most specifically, the invention relates to photovoltaic devices fabricated from nanocrystalline, hydrogenated semiconductor alloys, which devices exhibit enhanced performance and/or resistivity to photo degradation.

### BACKGROUND OF THE INVENTION

Nanocrystalline materials provide for some specific advantages in the fabrication of semiconductor devices, such as photovoltaic devices. However, nanocrystalline materials have, heretofore, been poorly understood, and as a consequence, their potential has not always been realized in particular applications. It has been found that in certain applications, nanocrystalline materials can exhibit light-induced metastabilities which degrade the performance of photovoltaic devices in which they are incorporated. In other instances, overall performance of photovoltaic devices which include nanocrystalline materials have not met theoretical expectations. Heretofore, there has been much speculation in the art regarding the nature and causes of metastabilities and other problems encountered in the use of nanocrystalline materials.

Nanocrystalline materials are understood in the art to comprise a group of materials having a morphology which is intermediate that of amorphous materials and crystalline materials. Amorphous materials are lacking in long range atomic order although they may have a degree of short range atomic order; conversely, crystalline materials have long range atomic order which is manifest in a large scale periodicity. Nanocrystalline materials include features with some degree of intermediate range order, which, in a general sense, is understood to be order on the range of up to 50 atomic diameters. The size of the features will depend upon the particular elements comprising the material; however, in general, intermediate range order is understood to encompass features in the general size range of 10-80 angstroms. In particular instances, the size range of the features having intermediate range order is approximately 10-50 angstroms, and in certain instances, this size range is approximately 30-50 angstroms.

Nanocrystalline materials can be understood as being composite materials having regions with different degrees of order. As for example, a nanocrystalline material can include regions which are substantially amorphous together with regions of intermediate range order having features of the aforementioned dimensions. It is further to be understood that nanocrystalline materials may also have inclusions which are of a higher degree of crystallinity. Nanocrystalline materials can manifest optical, electronic, and physical properties in common with both amorphous materials and crystalline materials. Additionally, they can also manifest unique properties. A description of nanocrystalline materials, within the context of silicon alloy semiconductor materials, is found in U.S. Pat. No. 6,087,580, the disclosure of which is incorporated herein by reference.

Nanocrystalline materials may be characterized and described with reference to various parameters. One such parameter is termed “crystalline volume,” and this parameter describes the proportion of a bulk material which is in a crystalline, as opposed to noncrystalline, state. Another parameter of a nanocrystalline material is grain, or crystallite, size. This parameter describes the physical dimension of the ordered features of the material. As will be explained herein, the inventors have found that by control of these parameters, either jointly or in combination, the properties of a nanocrystalline semiconductor material may be controlled and tailored for particular applications. And, by appropriate control of these parameters, the performance characteristics of photovoltaic devices and other semiconductor devices produced therefrom may be controlled.

This invention will be explained with reference to p-i-n type photovoltaic devices; however, it is to be understood that the principles presented herein may be likewise applied to other photovoltaic devices including p-n junction devices, Schottky barrier devices and the like. This invention may also be applied to still other semiconductor devices, including photoresponsive devices such as photosensors, electrophotographic members, and the lice, as well as to nonphotoresponsive devices such as circuit elements.

For purposes of explanation, this disclosure will focus upon photovoltaic devices of the p-i-n type. These devices, as is known in the art, comprise a body of substantially intrinsic photovoltaic material interposed between a layer of p-doped semiconductor material and a layer of n-doped semiconductor material. It is to be understood that the layer of intrinsic semiconductor material may inherently be slightly p type in its conductivity, or slightly n type in its conductivity, as a result of material properties, deposition conditions, or the like. However, such materials, as used in these devices, function as intrinsic semiconductor materials, and hence the term “substantially intrinsic” is to be understood to include material which is fully intrinsic, as well as material which may be slightly p or n type. As is known in the art, in p-i-n type photovoltaic devices, the substantially intrinsic layer absorbs incident light and generates carrier pairs, which are separated by an internal field created by the p-doped and n-doped layers. These carriers are collected by electrodes associated with the doped layers and carried to an external circuit.

In some instances, the semiconductor materials comprising the intrinsic layer can exhibit light-induced metastabilities which degrade the performance of the photovoltaic device. Heretofore, there has been much speculation in the prior art regarding the nature and causes of such metastabilities in nanocrystalline materials, and a number of diverse, and in some instances conflicting, theories have been suggested to explain the nature and causes of these effects. As will be explained herein, the present inventors have determined mechanisms and factors which have led to problems and confusion with regard to applications of nanocrystalline materials to semiconductor devices. Disclosed herein are material and device configurations which provide for the manufacture of stable, high efficiency semiconductor devices.

### BRIEF DESCRIPTION OF THE INVENTION

Disclosed is a photovoltaic device having an enhanced resistance to light-induced degradation. The device is of a p-i-n type configuration and as such includes a p layer comprised of a p-doped semiconductor material, an n layer comprised of an n-doped semiconductor material, and an i layer comprised of a substantially intrinsic, nanocrystalline semiconductor material interposed between the p layer and the n layer. In specific instances, the crystalline volume of the semiconductor material comprising the i layer decreases as the thickness of the layer increases from its interface with the n layer to its interface with the p layer. In further instances, the grain size of the substantially intrinsic nanocrystalline semiconductor material decreases as the thickness of the i layer increases from its interface with the n layer to its interface with the p layer.

In particular instances, the i layer is configured such that the volume of regions of intermediate range order in a portion of the i layer commencing at its interface with the p layer, and comprising no more than 50% of the thickness of the i layer, is greater than is the volume of regions of intermediate range order in the remainder of the i layer. In particular instances, the portion having the greater volume of regions of intermediate range order is no more than 30% of the thickness of the i layer, while in yet other instances, it is no more than 10% of the thickness of the i layer.

In specific instances, the nanocrystalline material includes regions of intermediate range order having features in the size range of 10-80 angstroms. In particular instances, this size range is 10-50 angstroms, and in still other instances, it is 30-50 angstroms. In yet other instances, the regions of intermediate range order have features which are no more than 50 times the average atomic diameter of the elements comprising the substantially intrinsic semiconductor material. In some specific instances, the substantially intrinsic nanocrystalline semiconductor material comprises a hydrogenated group IV semiconductor alloy material, and this alloy may be an alloy of silicon and/or germanium.

Also disclosed herein are methods for making the foregoing devices. In particular instances, the morphology and nature of the substantially intrinsic layer is controlled by controlling parameters of the process by which the layer is prepared. In one particular instance, the substantially intrinsic layer is prepared by a plasma deposition process in which a process gas, which includes a precursor of the semiconductor material, is subjected to an input of electromagnetic energy which creates a plasma from that process gas. This plasma deposits the substantially intrinsic semiconductor material on a substrate maintained in proximity thereto. In this process, the concentration of a diluent material in the process gas is varied during the deposition of the substantially intrinsic semiconductor layer so that the process gas is more dilute when that portion of the i layer proximate the n layer is being deposited, as compared to when that portion of the i layer which is proximate the p layer is being deposited. The diluent gas may comprise hydrogen, and the degree of dilution may be varied continuously, or in a stepwise manner.

### BRIEF DESCRIPTION OF THE DRAWING

FIG. 1 is a cross-sectional view of a typical p-i-n type photovoltaic device;

FIG. 2 is a set of Raman spectra for a photovoltaic device, taken at green and red wavelengths;

FIG. 3 is a plot of the initial and stable efficiencies of the cells of FIG. 2, as compared with the morphologies of the relative i-layers as determined from the Raman data; and

FIG. 4 is a set of graphs illustrating the performance characteristics of a particular triple tandem photovoltaic device.

### DETAILED DESCRIPTION OF THE PREFERRED EMBODIMENTS

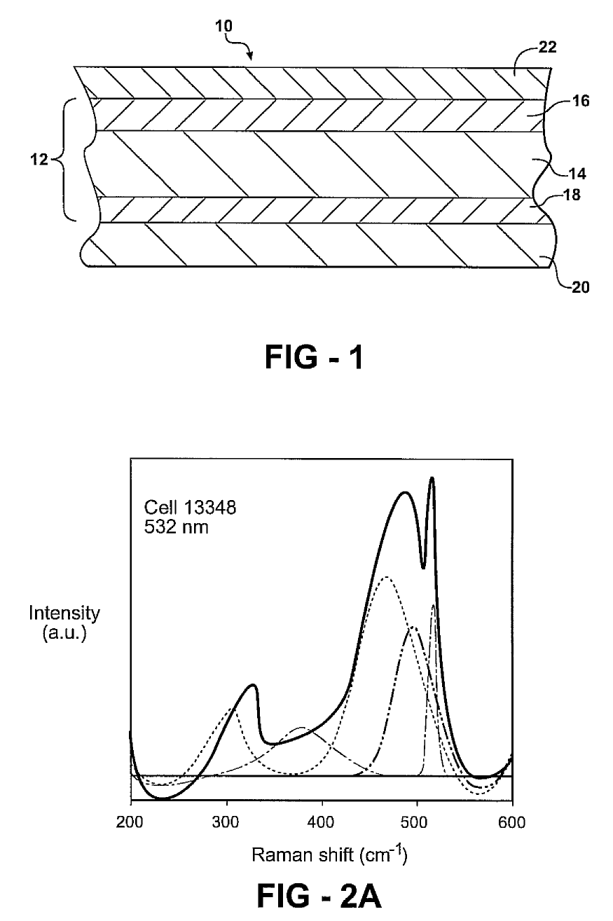

Referring now to FIG. 1, there is shown a p-i-n type photovoltaic device 10 of the type in which the present invention may be implemented. As is known in the art, photovoltaic devices of this type include at least one triad of semiconductor layers 12. This triad 12 is comprised of a layer of substantially intrinsic semiconductor material 14 interposed between a layer of p-doped semiconductor material 16 and a layer of n-doped semiconductor material 18. The photovoltaic device 10 further includes a support substrate 20. The substrate 20, as is known in the art, may comprise an electrically conductive body, such as a body of metal, and in that regard will function as an electrode of the photovoltaic device 10. The substrate 20 may also, in some instances, comprise an electrically insulating body such as a polymeric or glass member, having an electrically conductive layer of material thereupon. As is further known in the art, the substrate 20 may include additional layers such as light reflecting layers, texturing layers, current buffering layers, and the like. The photovoltaic device 10 further includes a top electrode 22 which, in those instances where the substrate 20 is opaque, is fabricated from a transparent electrically conductive material such as a body of an electrically conductive oxide material such as indium tin oxide. As is further known in the art, the top electrode may include current collecting structures such as grid members, bus bars and the lice.

In some instances, p-i-n type photovoltaic devices may be comprised of a plurality of triads 12 stacked in an optical and electrical series relationship. These devices are referred to in the art as tandem devices. In some instances, the materials comprising the various triads of a tandem device may be selected so that the wavelength response of the device may be adjusted to address a broad portion of the optical spectrum.

There are a variety of photovoltaic materials which may be utilized in the fabrication of devices of this type. In one particular group of instances, photovoltaic devices are fabricated to include semiconductor layers comprised of thin film alloys of group IV semiconductor materials. For example, in particular types of photovoltaic devices, the intrinsic layer of the device is fabricated from a hydrogenated alloy of silicon, germanium, or silicon/germanium. The p-doped 16 and n-doped 18 layers may likewise be fabricated from thin film group IV alloy materials, or they may be fabricated from other materials. All of such device configurations are known in the art, and may be used in the practice of this invention.

It has been found that a p-i-n type photovoltaic device will have enhanced resistance to light-induced degradation when the intrinsic layer is fabricated from a nanocrystalline semiconductor material configured so that the crystalline volume in the intrinsic layer decreases as the thickness of the layer increases from its interface with the n-doped layer to its interface with the p-doped layer. As will be explained in detail hereinbelow, control of crystalline volume may be controlled by controlling the deposition parameters used in the fabrication of the layer.

It has also been found that photovoltaic device performance and quality is increased when the substantially intrinsic layer is configured so that the crystalline volume in that layer is greater in the region proximate its interface with the p-doped layer, as compared to the crystalline volume in the bulk of the material. In certain aspects of the invention, this region of higher crystalline volume comprises 10-50% of the thickness of the intrinsic layer.

It has also been found that device performance is enhanced when the nanocrystalline intrinsic layer is configured so that the intermediate range order of that layer increases as the thickness of the layer increases from its interface with the n-doped layer to its interface with the p-doped layer. This increase in intermediate range order may be continuous throughout the thickness of the intrinsic layer, or it may occur in a stepwise manner so that a portion of the layer proximate the interface with the p-doped layer has the highest proportion of material with intermediate range order. This portion may comprise 10-50% of the thickness of the layer.

Semiconductor layers of the type utilized in the devices disclosed herein may be prepared by a plasma-enhanced chemical vapor deposition process wherein electromagnetic energy excites a process gas, which process gas includes precursors of the semiconductor materials, and decomposes these precursors so as to create a plasma, containing deposition species which species deposit as a layer of semiconductor material onto a substrate maintained in, or in proximity to, the plasma. By control of the various parameters of the deposition process, including process gas composition, gas pressure, the frequency of the electromagnetic energy, the intensity of the electromagnetic energy, and others, the nature and quality of the deposited semiconductor material may be controlled.

In a first experimental series, a number of single junction photovoltaic devices were prepared in accord with the foregoing deposition process. The nanostructure of the nanocrystalline intrinsic layer was controlled by controlling the profile of a hydrogen diluent in the process gas, in either a continuous or stepwise manner, and as is known in the art, the degree of crystallinity in the material is correlatable with process gas dilution. The stability of the devices to photodegradation was evaluated by light soaking the devices with a white light illumination of 100 mW/cm² at 50° C. The current density versus voltage (J-V) characteristics of the devices were measured under AM1.5 illumination in a solar simulator at 25° C. Quantum efficiency (QE) of the devices was measured from 300 nm to 1100 nm. The material structure of the intrinsic layer was directly measured on the solar cells using Raman spectroscopy with different excitation wavelengths.

Data from six devices made and evaluated in accord with the foregoing is summarized in Table I hereinbelow.

TABLE I
Initial (A) and stable (B) performance of nc-Si:H cells. (C) refers to the percentage of
light-induced change.

| Run # | Dep. Method | H Dilution | State | Eff (%) | J_{sc} (mA/cm²) | V_{oc} (V) | FF |
|---|---|---|---|---|---|---|---|
| 10514 | RF | Constant | A | 7.85 | 23.06 | 0.499 | 0.682 |
| | | | B | 6.73 | 22.44 | 0.470 | 0.638 |
| | | | C | −14.3% | −2.7% | −5.8% | −6.5% |
| 10521 | RF | Constant | A | 7.21 | 23.03 | 0.461 | 0.679 |
| | | | B | 6.12 | 22.65 | 0.426 | 0.634 |
| | | | C | −15.1% | −1.7% | −7.6% | −6.6% |
| 10505 | RF | Dynamic | A | 7.56 | 22.76 | 0.520 | 0.638 |
| | | Profiling | B | 7.30 | 22.91 | 0.517 | 0.616 |
| | | | C | −3.5% | +0.7% | −0.6% | −3.4% |
| 12085 | MVHF | Step Profiling | A | 6.62 | 21.76 | 0.479 | 0.635 |
| | | | B | 6.06 | 21.65 | 0.470 | 0.596 |
| | | | C | −8.5% | −0.5% | −1.9% | −6.1% |
| 13324 | MVHF | Dynamic | A | 6.75 | 23.89 | 0.490 | 0.577 |
| | | Profiling | B | 6.52 | 23.16 | 0.481 | 0.585 |
| | | | C | −3.4% | −3.1% | −1.8% | +1.4% |
| 13348 | MVHF | Dynamic | A | 7.82 | 22.72 | 0.524 | 0.657 |
| | | Profiling | B | 7.72 | 21.85 | 0.527 | 0.670 |
| | | | C | −1.3% | −3.9% | +0.6% | +2.0% |

As is shown in the table, the intrinsic layer of the devices was fabricated, in some instances by utilizing radiofrequency (RF) energy to create and excite the deposition plasma; while in other instances, a modified very high frequency (MVHF) technique was used for fabricating the intrinsic layers. The hydrogen dilution of the process gas was variously controlled. In some instances, the dilution was maintained at a constant throughout the deposition of the thickness of the layer of intrinsic material. In other instances, the hydrogen dilution was varied, on a continuous basis, throughout the deposition, and this profile is referred to as “dynamic profiling.” In another instance, the profile was varied in a stepwise manner. Parameters of the devices in terms of efficiency, short circuit current, open circuit voltage, and fill factor, were measured both before and after light soaking.

As will be seen from the table, the first two cells, using radiofrequency deposition of the intrinsic layer and a constant hydrogen dilution, show a very large light induced degradation, approximately 14-15%, mainly due to reductions in open circuit voltage and fill factor. The third cell with an optimized hydrogen dilution profiling shows only a 3.5% light induced degradation. Similarly, in the MVHF cells, the cell produced with stepwise hydrogen dilution profiling showed an 8.5% light induced degradation, which is somewhat lower than that for the RF cells with constant hydrogen dilution, but larger than that for the dynamically profiled cells in the MVHF process. The open circuit voltage and fill factor in the 13348 MVHF cell did not degrade after prolonged light soaking; in fact, the fill factor of this cell slightly improved.

As will be seen from the foregoing, in this experimental series, control of deposition parameters so as to control the morphology of the intrinsic layers in accord with the foregoing, has significantly improved the performance and stability of the photovoltaic cells.

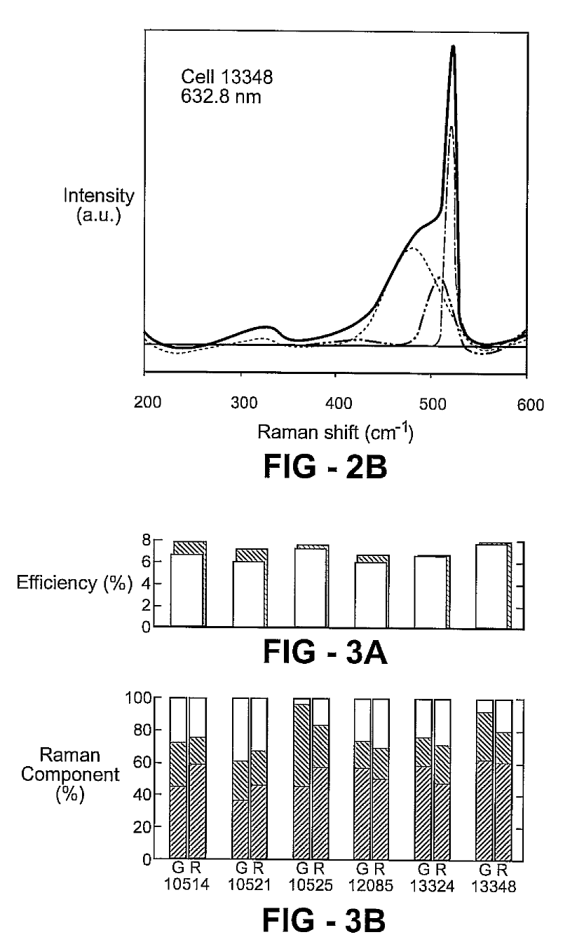

In a further experimental series, and in order to obtain a better understanding of the mechanism of the light induced degradation of the nanocrystalline cells, and their relation to the deposition process and material structures, Raman measurements were carried out directly on the foregoing six cells. FIG. 2 shows the Raman spectra of the 11348 sample excited with a green (532 nm) laser and with a red (632.8 nm) laser. The green light probes the material structure in the top layer near the i-p interface, while the red light reveals information from the bulk of the intrinsic layer. Based on the two spectra, one can clearly see that the region near the i-p interface has lower crystalline volume fraction than does the bulk of the intrinsic layer. The Raman spectra was deconvoluted into different components of amorphous LA (approximately 310 cm⁻¹), LO (approximately 380 cm⁻¹), TO (approximately 480 cm⁻¹), intermediate (approximately 500 cm⁻¹), and crystalline (approximately 520 cm⁻¹) modes. Table II lists the parameters of the amorphous, TO, intermediate, and crystalline modes.

TABLE II
Raman deconvolution data for six nc-Si:H solar cells measured with green (532.0 nm)
and red (632.8 nm) lasers. a, i, and c denote the three peaks corresponding to the
amorphous TO, intermediate, and the crystalline TO peaks. p, w, and f denote the peak
position, width, and area percentage of each peak.

| | | a | | | i | | | c | | |
|---|---|---|---|---|---|---|---|---|---|---|
| Run | λ | pₐ | wₐ | fₐ | pᵢ | wᵢ | fᵢ | p_{c} | w_{c} | f_{c} |
| # | (nm) | (cm⁻¹) | (cm⁻¹⁻) | (%) | (cm⁻¹) | (cm⁻¹⁻) | (%) | (cm⁻¹) | (cm⁻¹) | (%) |
| 10514 | 532.0 | 469.1 | 78.7 | 45.1 | 501.2 | 37.8 | 27.3 | 517.1 | 10.2 | 27.6 |
| | 632.8 | 481.6 | 65.7 | 59.0 | 510.7 | 21.5 | 16.7 | 519.1 | 10.3 | 24.3 |
| 10521 | 532.0 | 483.7 | 65.5 | 36.5 | 508.4 | 27.6 | 24.7 | 518.6 | 10.2 | 38.9 |
| | 632.8 | 485.4 | 65.6 | 46.1 | 511.6 | 24.3 | 21.2 | 520.9 | 10.3 | 32.8 |
| 10505 | 532.0 | 457.5 | 70.1 | 45.2 | 486.8 | 53.9 | 50.9 | 514.2 | 13.1 | 3.9 |
| | 632.8 | 471.3 | 64.8 | 57.0 | 499.4 | 41.2 | 26.5 | 518.1 | 11.2 | 16.5 |
| 12085 | 532.0 | 479.4 | 69.9 | 56.5 | 505.5 | 29.1 | 17.1 | 518.6 | 11.6 | 26.4 |
| | 632.8 | 483.5 | 63.8 | 49.9 | 509.7 | 24.3 | 19.6 | 520.0 | 11.2 | 30.5 |
| 13324 | 532.0 | 480.8 | 67.0 | 58.0 | 508.4 | 26.1 | 18.4 | 518.6 | 8.7 | 23.5 |
| | 632.8 | 484.4 | 65.6 | 47.3 | 511.6 | 25.2 | 23.9 | 520.9 | 9.3 | 28.8 |
| 13348 | 532.0 | 467.7 | 68.5 | 61.8 | 496.8 | 43.6 | 30.4 | 518.6 | 10.2 | 7.7 |
| | 632.8 | 480.7 | 63.8 | 60.1 | 508.8 | 29.0 | 19.1 | 520.0 | 10.3 | 20.8 |

It is common to determine the crystalline volume fraction from the area under each deconvoluted curve, with a correction factor for the grain size dependence of Raman cross section. For simplicity, only the ratio of areas for each component is set forth. To emphasize the key points, FIG. 3 plots (upper panel) initial and stable efficiencies with a comparison to (lower panel) the fractions of each Raman component obtained by deconvolution of the Raman spectra measured using the green and red lasers. From Table II and FIG. 3, three important phenomena are observed. First, the crystalline volume fraction (the narrow peak at approximately 520 cm⁻¹) is higher for the green laser than the red laser in the samples with constant hydrogen dilution (sample 10514), as normally observed in the nanocrystalline evolution with thickness. The optimized hydrogen dilution profiling (samples 10505 and 13348) reversed this trend and resulted in a lower crystalline volume fraction in the region near the i-p interface. Second, the stable cells have lower crystalline volume fractions than those with high light induced degradation, especially at the i-p interface region as probed by the green light. Third, although the crystalline peak is smaller in the stable cells than in the unstable samples, the intermediate range peak is not smaller. In fact, it becomes broader, and shifts to lower wave numbers.

From the foregoing observation it is apparent that the light-induced degradation in the particular nanocrystalline silicon:hydrogen alloy materials does not increase, with increasing amorphous volume fraction, as was suggested in the prior art. Instead, it decreases. Also, it appears that stable cells have a relatively large and broad intermediate Raman peak. This Raman peak is indicative of intermediate range order, and this order plays a role in the enhanced stability of the devices. While not wishing to be bound by speculation, the regions of intermediate range order may be due to linear like structures formed in high hydrogen dilution plasmas and/or from grain boundaries. The improved stability of the high hydrogen diluted semiconductor material is correlated with intermediate range order.

It appears that in the experimental series, when the nanocrystalline intrinsic layer was deposited under a controlled hydrogen dilution profiling, even though a significant amount of small grains was incorporated into the material, they were not allowed to grow into larger grains. These small grains may not contribute to the sharp crystalline Raman peak, but can contribute to the intermediate peak. From the correlation between the solar cell stability results and the Raman analyses, it is apparent that the presence of a large amount of small grains in intermediate range order, especially near the i-p interface, favors stability.

The increase of intermediate range order along the growth direction of the device is also an important factor. It is known that the i-p interface of p-i-n cells is the dominant junction. The presence of small grains with a reasonable amount of amorphous component in the i-p interface region ensures a good grain boundary passivation and a compact material structure, which reduces defect density and impurity diffusion. As a result, the open circuit voltage of cells thus configured is improved. The high crystalline volume fraction in the bulk of the nanocrystalline intrinsic layer, especially in the n-i region, ensures sufficient long wavelength absorption resulting in a high short circuit density. This also provides high mobility paths for carrier transport resulting in an improved fill factor.

It may be expected that the amorphous component in the i-p region would cause extra light induced degradation. In fact, it is true that the short circuit current in some hydrogen dilution profiled nanocrystalline silicon:hydrogen cells such as numbers 13324 and 13348 of Table I decreases due to the short wavelength response. This reduced short wavelength response is due to recombination in the amorphous phase near the i-p interface, and can be annealed back at high temperature. It is also observed that a loss of fill factor measured under blue light occurred. From the foregoing, it is apparent that a decrease of crystalline volume fraction and grain size along the growth direction of a nanocrystalline cell structure, near the i-p interface is beneficial for cell performance and stability. This feature can be obtained by reducing hydrogen dilution during the deposition of the cell wherein the intrinsic layer is deposited onto an n-doped layer, and can occur naturally when an inversely configured cell is prepared wherein the intrinsic layer is deposited onto the p-doped layer.

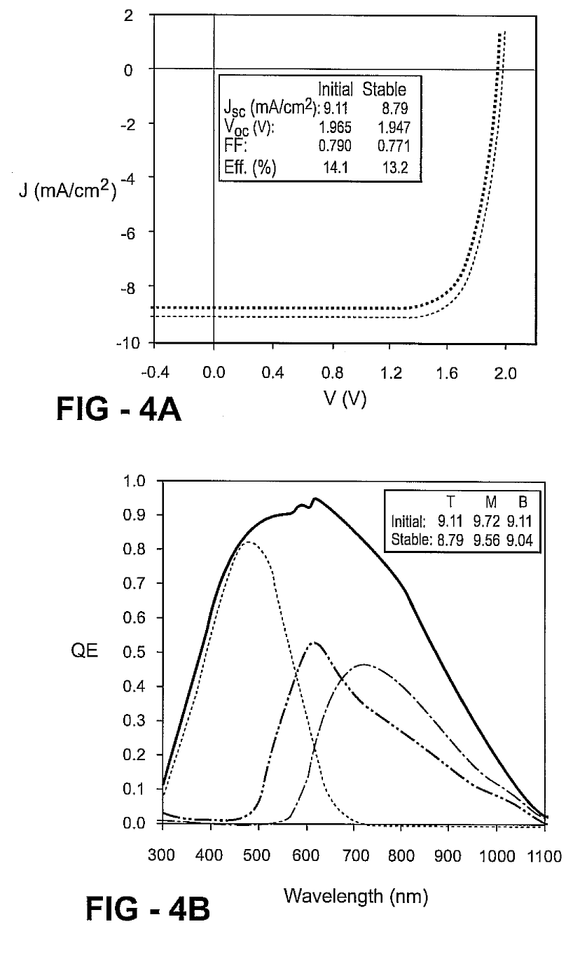

Based upon the foregoing principles and observations, a p-i-n type cell was prepared incorporating a nanocrystalline intrinsic layer of a silicon hydrogen alloy. This single junction cell showed an initial active area efficiency of 9.06%. A triple junction cell was prepared in accord with the foregoing principles. The triple junction cell included nanocrystalline intrinsic layers in the middle and bottom cells of the stack. This triple junction cell achieved an initial active area efficiency of 14.1%, and had an efficiency of 13.2% following prolonged light soaking. FIG. 4 shows the initial and stable (a) current voltage characteristics and (b) quantum efficiency of this triple junction device. The overall cell performance degradation is only 6.4% after prolonged light soaking.

Conclusions drawn from the foregoing are that, first of all, the amorphous component is not the determining factor for the light induced degradation of nanocrystalline semiconductor materials; second, smaller grains and intermediate range order and/or better grain boundary passivation improves cell stability; and third, the decrease of crystalline volume fraction along the growth direction of an n-i-p structure, especially near the i-p interface, improves the cell performance and stability. This can be accomplished by an optimized hydrogen dilution profile.

While the foregoing has been described with reference to particular configurations of photovoltaic devices, it is to be understood that these principles may be extended to other configurations of photovoltaic devices, as well as to other photoresponsive devices, and to semiconductor devices in general in which control of photodegradation and/or transport properties is beneficial. In view of the teaching presented herein, numerous modifications and variations of the methods and materials shown herein will be apparent to those of skill in the art. The foregoing is illustrative of specific embodiments and implementations of the invention, but is not meant to be a limitation upon the practice thereof.

1. A photovoltaic device having an enhanced resistance to light-induced degradation, said device comprising:
a p-layer comprised of a p-doped semiconductor material;
an n-layer comprised of an n-doped semiconductor material; and
an i-layer comprised of a substantially intrinsic, nanocrystalline semiconductor material interposed between said p-layer and said n-layer; wherein the crystalline volume in said i-layer decreases as the thickness of said layer increases from its interface with the n-layer to its interface with the p-layer.

2. The device of claim 1, wherein the grain size of the substantially intrinsic nanocrystalline semiconductor material decreases as the thickness of said i-layer increases from its interface with the n-layer to its interface with the p-layer.

3. The device of claim 1, wherein in the substantially intrinsic semiconductor material, the volume of regions of intermediate range order in that portion of said i-layer commencing at the interface of said i-layer and said p-layer, and comprising no more than 50% of the thickness thereof, is greater than is the volume of regions of intermediate range order in the remainder of said i-layer.

4. The device of claim 3, wherein said portion of said i-layer comprises no more than 30% of the thickness thereof.

5. The device of claim 3, wherein said portion of the i-layer comprises no more than 10% of the thickness thereof.

6. The device of claim 3, wherein said regions of intermediate range order have features in the range of 10-80 angstroms.

7. The device of claim 3, wherein said regions of intermediate range order have features in the range of 10-50 angstroms.

8. The device of claim 3, wherein said regions of intermediate range order have features in the range of 30-50 angstroms.

9. The device of claim 3, wherein the regions of intermediate range order have features which are no more than 50 times the average atomic diameter of the elements comprising said substantially intrinsic semiconductor material.

10. The device of claim 1, wherein said substantially intrinsic, nanocrystalline semiconductor material comprises a hydrogenated group IV semiconductor alloy.

11. The device of claim 10, wherein said hydrogenated group IV semiconductor alloy comprises an alloy containing silicon and/or germanium.

12. The device of claim 1, wherein the intermediate range order of said i-layer increases as its thickness increases from its interface with the n-layer to its interface with the p-layer.

13. A photovoltaic device comprising:
a p-layer comprised of a p-doped semiconductor material;
an n-layer comprised of an n-doped semiconductor material; and
an i-layer comprised of a substantially intrinsic, nanocrystalline semiconductor material interposed between said p-layer and said n-layer; wherein the intermediate range order of said i-layer increases as the thickness thereof increases from its interface with the n-layer to its interface with the p-layer.

14. The device of claim 13, wherein the intermediate range order is defined by the relative volume of crystallites in said material having a size in the range of 10-80 angstroms.

15. The device of claim 13, wherein the n-doped semiconductor material comprises a substantially amorphous, hydrogenated, group IV semiconductor alloy material, and the p-doped semiconductor material comprises a nanocrystalline, hydrogenated, group IV semiconductor alloy material.

16. A method of making a p-i-n photovoltaic device of the type which comprises a layer of substantially intrinsic, nanocrystalline, semiconductor material interposed between a layer of a p-doped semiconductor material and a layer of an n-doped semiconductor material, said method comprising:
preparing said layer of substantially intrinsic semiconductor material by a plasma deposition process wherein a process gas, which includes a precursor of said substantially intrinsic semiconductor material, is subjected to an input of electromagnetic energy which creates a plasma therefrom, which plasma deposits said substantially intrinsic semiconductor material on a substrate; wherein the concentration of a diluent in said process gas is varied during the deposition of the substantially intrinsic semiconductor material so that the diluent concentration in the process gas is greater when a portion of the thickness of the substantially intrinsic semiconductor layer which is closer to the layer of n-doped semiconductor material is being deposited, than it is when a portion of the thickness of the layer of substantially intrinsic semiconductor material which is closer to the p-doped layer of semiconductor material is being deposited.

17. The method of claim 16, wherein said diluent is hydrogen.

18. The method of claim 16, wherein the concentration of said diluent is varied in a stepwise manner during the time that said layer of substantially intrinsic semiconductor material is being deposited.

19. The method of claim 16, wherein the concentration of said diluent is varied in a continuous manner during the time that said layer of substantially intrinsic semiconductor material is being deposited.

20. The method of claim 16, wherein said layer of substantially intrinsic semiconductor material comprises a hydrogenated alloy of silicon and/or germanium.
